(19) United States
(12) Patent Application Publication
(10) Pub. No.: US 2019/0069404 A1
(43) Pub. Date: Feb. 28, 2019

(54) PRINTED CIRCUIT BOARD AND METHOD FOR MANUFACTURING THE SAME

(71) Applicants: Avary Holding (Shenzhen) Co., Limited., Shenzhen (CN); HongQiSheng Precision Electronics (QinHunangDao) Co., Ltd., Qinhunangdao (CN)

(72) Inventors: MENG-LU JIA, Shenzhen (CN); HAO-WEN ZHONG, Shenzhen (CN); HAI-BO QIN, Shenzhen (CN)

(21) Appl. No.: 15/833,149

(22) Filed: Dec. 6, 2017

(30) Foreign Application Priority Data
Aug. 31, 2017 (CN) 201710773939.5

(51) Int. Cl. H05K 1/11; H05K 1/03

(52) U.S. Cl. CPC H05K 1/11; H05K 3/0014; H05K 1/0353

(57) ABSTRACT

A printed circuit board comprises a base, a circuit layer, a circuit layer, a first insulating layer, and a second insulating layer. The circuit layer is on the base. The first insulating layer has a pattern, the first insulating layer is fixed on the base. The pattern of the first insulating layer matches a pattern of the circuit layer. The second insulating layer is laminated on the circuit layer and the first insulating layer. Openings are defined in the second insulating layer, the circuit layer is exposed from the openings.

### FIELD

The subject matter relates to printed circuit boards and manufacturing methods, and especially relates to a thick copper layer circuit board and a method for manufacturing the same.

### BACKGROUND

Circuit boards are widely used in various kinds of electronic devices. The circuit board may have a thick circuit layer, which can provide improved conductivity between electronic elements. However, the insulating layer between the circuit layers can form a plurality of pores in the insulating layer and between the circuit layers. The pores may cause the insulation layer to peel off and affect manufacturing efficiency.

### BRIEF DESCRIPTION OF THE DRAWING

Implementations of the present disclosure will now be described, by way of example only, with reference to the attached figures.

FIG. 1 is a flowchart showing a method for manufacturing a printed circuit board (PCB) in accordance with an embodiment of the present disclosure.

FIG. 2 is a cross sectional view of a PCB substrate of an exemplary embodiment of the present disclosure.

FIG. 3 is a cross sectional view showing the substrate of FIG. 2 etched to form a circuit layer.

FIG. 4 is a cross sectional view of forming a first insulating layer on the PCB of FIG. 1.

FIG. 5 is a cross sectional view showing the first insulating layer of FIG. 4 laminated on the substrate and the circuit layer of FIG. 3.

FIG. 6 is a cross sectional view showing a second insulating layer laminated on the circuit layer and the first insulating layer of FIG. 5.

FIG. 7 is a cross sectional showing a plurality of openings formed on the second insulating layer to form the PCB.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details.

In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

One definition that applies throughout this disclosure will now be presented.

The term “substantially” is defined to be essentially conforming to the particular dimension, shape, or other feature that the term modifies, such that the component need not be exact. For example, “substantially rectangular” means that the object resembles a rectangle, but can have one or more deviations from a true rectangle.

The term “comprising,” when utilized, means “including, but not necessarily limited to”; it specifically indicates open-ended inclusion or membership in the so-described combination, assembly, series, and the like.

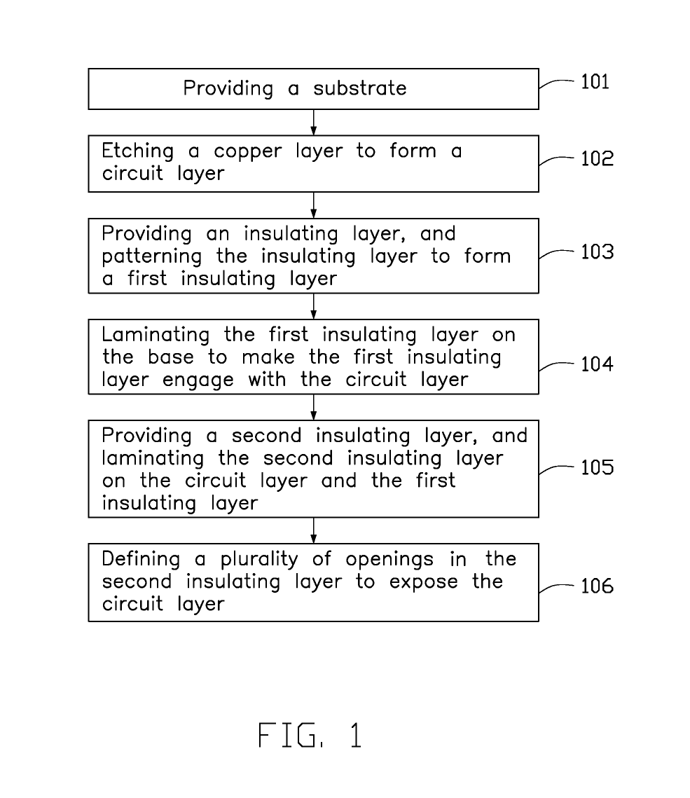

Referring to the FIG. 1, a method for manufacturing a printed circuit board (PCB 100, shown in FIG. 7) is illustrated. The exemplary method is provided by way of example, as there are a variety of ways to carry out the method. Each block shown in the figure represents one or more processes, methods, or subroutines, carried out in the exemplary method. Furthermore, the illustrated order of blocks is by example only, and the order of the blocks can change. Additional blocks may be added or fewer blocks may be utilized, without departing from this disclosure. The exemplary method can begin at block 101.

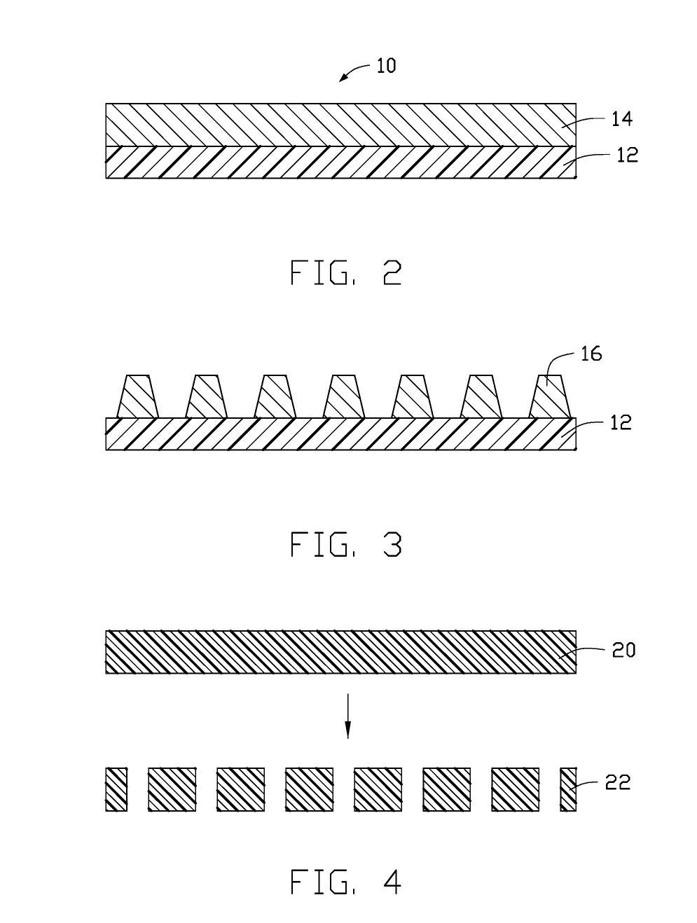

At block 101, referring to the FIG. 2, a substrate 10 is provided.

The substrate 10 comprises a base 12 and a copper layer 14. The copper layer 14 is formed on a surface of the base 12. In the exemplary embodiment, a thickness of the copper layer 14 is from 20 millimeters to 70 millimeters.

At block 102, referring to the FIG. 3, the copper layer 14 is etched to form a circuit layer 16.

At block 103, referring to the FIG. 4, an insulating layer 20 is provided, and the insulating layer 20 is patterned to form a first insulating layer 22.

A thickness of the first insulating layer 22 is not greater than a thickness of the circuit layer 16. In the exemplary embodiment, the thickness of the first insulating layer 22 is equal to the thickness of the circuit layer 16.

The first insulating layer 22 can be made by a mechanical cutting or laser cutting. The pattern of the first insulating layer 22 matches the pattern of the circuit layer 16.

At block 104, referring to the FIG. 5, the first insulating layer 22 is laminated on the base 12 to make the first insulating layer 22 engage with the circuit layer 16. In the exemplary embodiment, a top surface of the first insulating layer 22 is coplanar with a top surface of the circuit layer 16.

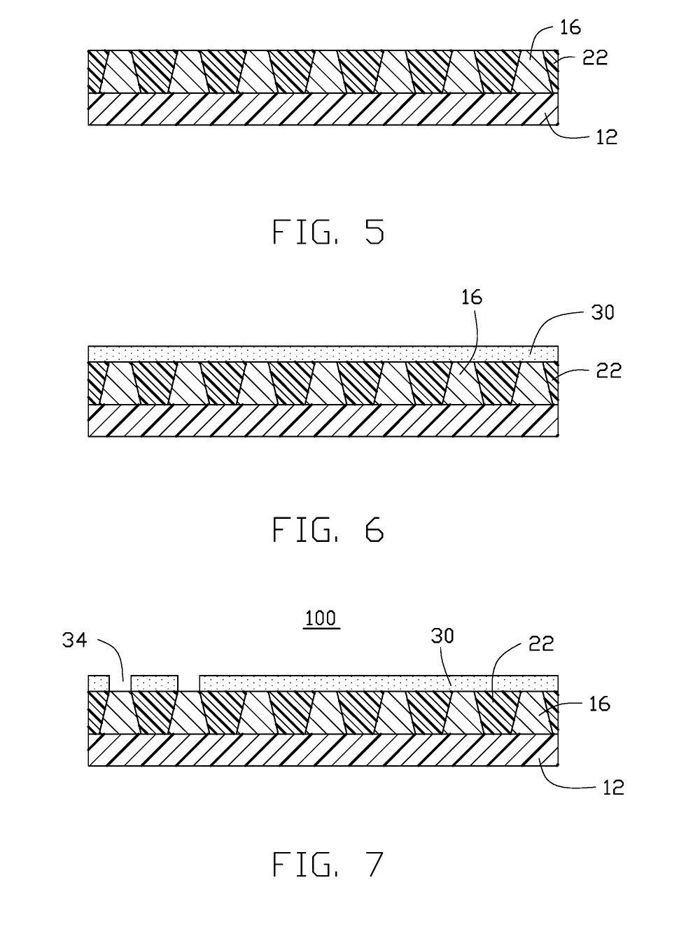

At block 105, referring to the FIG. 6, a second insulating layer 30 is provided, the second insulating layer 30 is laminated on the circuit layer 16 and the first insulating layer 22.

In the exemplary embodiment, the second insulating layer 30 and the first insulating layer 22 are made of same material. The second insulating layer 30 and the first insulating layer 22 can be made of at least one of polyimide (PI), polyethylene terephthalate (PET) or polyethylene glycol (PEN), prepreg (PP), and Ajinomoto Build-up film (ABF). Preferably, the second insulating layer 30 and the first insulating layer 22 are made of PP or ABF. Both the second insulating layer 30 and the first insulating layer 22 are semi-cured. When a thickness of the first insulating layer 22 is less than a thickness of the circuit layer 16, the second insulating layer 30 can fill the spaces between the wiring layers 16.

When the first insulating layer 22 and the second insulating layer 30 are made of the same material, in the exemplary embodiment, the first insulating layer 22 and the second insulating layer 30 are made of PP. The PP comprises glass fiber cloth. At least two different directions of glass fiber cloth are formed between the first insulating layer 22 and the second insulating layer 30. That is, there is a connection interface (not label) between the first insulating layer 22 and the second insulating layer 30.

In other exemplary embodiments, the first insulating layer 22 and the second insulating layer 30 are made of two different materials. The first insulating layer 22 is made of a fiber-reinforced resin (for example, glass fiber cloth). The first insulating layer 22 can shield against electromagnetic interference, dissipate heat, and provide rigidity. The second insulating layer 30 is made of PI or PP, and laminated on the circuit layer 16 and the first insulating layer 22 to protect the circuit layer 16 from being polluted.

At block 106, referring to the FIG. 7, a plurality of openings 34 are defined in the second insulating layer 30 to expose the circuit layer 16, thereby forming the PCB 100.

The plurality of openings 34 passes through the second insulating layer 30. A depth of the plurality of openings 34 is equal to a thickness of the second insulating layer 30.

Referring to the FIG. 7, the PCB 100 comprises the base 12, the circuit layer 16, the first insulating layer 22, and the second insulating layer 30. The circuit layer 16 is located on a surface of the base 12. The first insulating layer 22 has a pattern. The first insulating layer 22 is fixed to the base 12. The pattern of the first insulating layer 22 matches the pattern of the circuit layer 16. The thickness of the first insulating layer 22 is not more than the thickness of the circuit layer 16. The second insulating layer 30 is adhered to the circuit layer 16 and the first insulating layer 22. A plurality of openings 34 is defined in the second insulating layer 30. The circuit layer 16 is exposed from the plurality of openings 34.

The method of manufacturing the PCB 100 provides the second insulating layer 30 and the first insulating layer 22. The pattern of the first insulating layer 22 matches the pattern of the circuit layer 16, the first insulating layer 22 is laminated and fixed between the circuit layer 16, and the second insulating layer 30 is laminated on the first insulating layer 22 and the circuit layer 16 to avoid the generation of pores in the insulating layer 22. Additional rigidity is also provided to the insulating layer during the lamination of the first insulating layer 22.

The embodiments shown and described above are only examples. Many other details are often found in the art. Therefore, many such details are neither shown nor described. Even though numerous characteristics and advantages of the present disclosure have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

1. A printed circuit board comprising:
a base;
a circuit layer on the base;
a first insulating layer formed on the base, the first insulating layer having a pattern, wherein the pattern of the first insulating layer matches a pattern of the circuit layer; and
a second insulating layer laminated on the circuit layer and the first insulating layer, a plurality of openings defined in the second insulating layer, wherein the circuit layer is exposed from the plurality of the openings.

2. The printed circuit board of claim 1, wherein a depth of each of the plurality of openings is equal to a thickness of the second insulating layer.

3. The printed circuit board of claim 2, wherein a thickness of the first insulating layer is not greater than a thickness of the circuit layer.

4. The printed circuit board of claim 1, wherein the first insulating layer and the second insulating layer are made of a same material, at least two directions of glass fiber cloth are formed between the first insulating layer and the second insulating layer.

5. The printed circuit board of claim 1, wherein the first insulating layer and the second insulating layer are made of two different materials.

6. The printed circuit board of claim 5, wherein the first insulating layer is made of a fiber-reinforced resin.

7. A method of manufacturing a printed circuit board, comprising:
providing a substrate, wherein the substrate comprises a base and a circuit layer is formed on the base;
providing a first insulating layer, wherein the first insulating layer has a pattern;
fixing the first insulating layer on the base to make the pattern of the first insulating layer to be engaged with a pattern of the circuit layer; and
providing a second insulating layer, and laminating the second insulating layer on the circuit layer and the first insulating layer.

8. The method of claim 7, further comprising:
defining a plurality of openings in the second insulating layer to expose a portion of the circuit layer to form the printed circuit board.

9. The method of claim 7, wherein both the first insulating layer and the second insulating layer are semi-cured.

10. The method of claim 7, wherein the first insulating layer and the second insulating layer are made of prepreg, the prepreg comprises glass fiber cloth, two directions of glass fiber cloth are formed between the first insulating layer and the second insulating layer.
